(19) United States
(12) Patent Application Publication
(10) Pub. No.: US 2026/0150725 A1
(43) Pub. Date: May 28, 2026

(54) 3D STITCH-CHIP FOR HIGH-DENSITY INTEGRATED ELECTRONICS

(71) Applicant: GEORGIA TECH RESEARCH CORPORATION, Atlanta, GA (US)

(72) Inventors: Muhannad S. Bakir, Atlanta, GA (US); Shane Oh, Atlanta, GA (US); Zhonghao Zhang, Atlanta, GA (US)

(21) Appl. No.: 19/398,609

(22) Filed: Nov. 24, 2025

Related U.S. Application Data
(60) Provisional application No. 63/723,873, filed on Nov. 22, 2024.

(51) Int. Cl. H10W 70/60; H10W 44/20; H10W 70/63; H10W 90/00; H10W 90/10

(52) U.S. Cl. CPC H10W 70/616; H10W 44/209; H10W 44/216; H10W 44/243; H10W 70/635; H10W 90/10; H10W 90/401; H10W 90/724

(57) ABSTRACT

A semiconductor device includes a substrate; an integrated circuit chiplet on the substrate; a three-dimensional stitch-chip configured to electrically connect the substrate to the integrated circuit chiplet, the stitch-chip comprising: a bridging chiplet that is configured to electrically connect to the integrated circuit chiplet; and a through via chiplet configured to electrically connect to the bridging chiplet configured to provide a vertical signal transmission path to the bridging chiplet.

### CROSS-REFERENCE TO RELATED APPLICATION

This application claims priority to U.S. Provisional Application No. 63/723,873, filed on Nov. 22, 2024, the disclosure of which is incorporated herein by reference in its entirety.

### STATEMENT OF GOVERNMENT SUPPORT

This invention was made with government support under contract FA8650-20-C-1003 awarded by the United States Air Force. The government has certain rights in the invention.

### FIELD OF THE INVENTION

The present invention relates to 3D stitch-chips for high-density integrated electronics.

### BACKGROUND OF THE INVENTION

Advances in radio frequency (RF) and millimeter-wave (mmWave) technology have empowered applications such as fifth-generation (5G) technology for mobile communication, radar sensors for automotive driver assistance systems (ADASs), and beyond. These applications demand high-speed interconnections that meet specific performance, energy efficiency, and reliability requirements. Heterogeneous integration (HI) is required in the integration of various radio frequency integrated circuit (RFIC) and monolithic microwave IC (MMIC) intellectual property (IP) blocks, often manufactured using different substrate materials, process nodes, and technologies. As traditional packaging methods reach their performance limits, the need for more advanced packaging solutions is becoming increasingly evident.

Interconnections for high-speed signaling and RF applications mainly consist of three categories: 1) wire-bonding; 2) die-embedding; and 3) flip-chip bonding, each with unique benefits and drawbacks. The wire bond approach is a well-established interconnection method, but suffers from parasitic inductance at higher frequencies, leading to difficulties in broadband impedance matching. Die-embedding, implemented either through placing chiplets in cavities or building redistribution layers (RDLs) on and around chiplets, improves electrical performance by shortening the interconnection length. It can also help meet market demands, provided that difficult process challenges and reliability concerns are adequately answered. Additive printing methods, such as aerosol jet printing, offer flexible conductive patterning over dielectric-filled cavities and nonplanar surfaces. The flip-chip approach shortens the interconnect length even further, promising enhanced electrical performance such as lower reflections and better transmission. However, this approach reduces thermal dissipation paths, requiring design considerations to reduce thermal resistance through thermal bumps or utilizing thermally advantaged underfill materials. Furthermore, the electrical behavior of the IP may drift out of tune due to the proximity of the package. There is a growing need for an interconnection solution that have improved signal integrity and address various process challenges.

### SUMMARY

In some embodiments, a semiconductor device includes a substrate; an integrated circuit chiplet on the substrate; a three-dimensional stitch-chip configured to electrically connect the substrate to the integrated circuit chiplet, the stitch-chip comprising: a bridging chiplet that is configured to electrically connect to the integrated circuit chiplet; and a through via chiplet configured to electrically connect to the bridging chiplet configured to provide a vertical signal transmission path to the bridging chiplet.

### BRIEF DESCRIPTION OF THE DRAWINGS

FIGS. 1A-1B are cross-sectional views of a semiconductor device having three-dimensional stitch-chips electrically connecting an integrated circuit chiplet and a substrate according to some embodiments.

FIG. 2 is a cross-sectional view of a semiconductor device having a three dimensional stitch-chip electrically connecting two integrated circuit chiplets and a substrate according to some embodiments.

FIG. 3 is a cross-sectional view of a semiconductor device having a three-dimensional stitch-chip electrically connecting die on a substrate according to some embodiments.

FIGS. 4A-4D illustrate steps of mounting a three-dimensional stitch-chip using a waffle pack and bonder head according to some embodiments.

FIGS. 5-6 are cross-sectional views of a semiconductor device having three-dimensional stitch-chips electrically connecting an integrated circuit chiplet and a substrate according to some embodiments.

FIG. 7 is a cross-sectional view of a semiconductor device having three-dimensional stitch-chips electrically connecting an integrated circuit chiplet and a substrate according to some embodiments.

FIG. 8 is a perspective view of an assembly process for positioning a three-dimensional stitch-chip according to some embodiments.

FIGS. 9A-9F are schematic drawings of various simulation models. In FIG. 9A, port 1 is the chip side and port 2 is the board side, with the cutting plane used to clip the simulation models. FIGS. 9B-9E illustrate wire-bonding connections (FIG. 9B), die embedding connections (FIG. 9C), a ramped interconnect (FIG. 9D), and flip-chip bonding (FIG. 9E).

FIG. 9F illustrates a three-dimensional stitch-chip according to embodiments of the current invention.

FIGS. 9G-9J are graphs of the electrical simulation results of various interconnects, including interconnects according to some embodiments.

FIG. 10A is a simulation model of a through via chiplet according to some embodiments.

FIGS. 10B-10C are graphs illustrating characteristic impedance (FIG. 10B) and S-parameters as a function of through silicon via diameter (FIG. 10C), where the through silicon via height and pitch are at 300 and 250 μm, respectively.

FIG. 11A is a diagram of a simulation model of a stitch-chip according to some embodiments.

FIG. 11A is a graph of an optimization result according to some embodiments.

FIG. 11B is a time domain reflectometry graph at the narrow pitch side of the simulation model of FIG. 11A.

FIG. 12A is a schematic image of an HFSS simulation model according to some embodiments.

FIGS. 12B-12E are graphs of electrical simulations of the model for TSV chiplet width (FIG. 12B), length sweep (FIG. 12C), bump diameter (FIG. 12D), and height sweep (FIG. 12E) in μm units.

FIGS. 13A-13D are schematic diagrams of the fabrication process of the stitch-chip according to some embodiments in which a fused silica wafer is patterned with a negative photoresist (FIG. 13A), metal is evaporated onto the wafer (FIG. 13B), unwanted metal is removed through a lift off process (FIG. 13C), and gold stud bumps are formed onto the metal pads (FIG. 13D).

FIGS. 14A-14B illustrate a fabrication process snapshot for the stitch-chip fabrication illustrated in FIGS. 13A-13D in which a dark field microscope image reveals alignment markers surrounding the CPW traces (FIG. 14A) and a single gold stud bump is illustrated in an SEM image (FIG. 14B).

FIGS. 15A-15B are schematic illustrations of a stitch-chip assembly according to some embodiments.

FIGS. 16A-16C are images of fabrication components of a three-dimensional stitch-chip according to some embodiments, including a through via chiplet (FIG. 16A), a bridging chiplet (FIG. 16B), and an assembled three-dimensional stitch-chip (FIG. 16C).

FIGS. 17A-17B are schematic illustrations of a dummy chip that is flip-chip bonded onto a substrate or board to form a test vehicle according to some embodiments.

FIGS. 18A-18D are optical images of the test vehicle components and various interconnections, including a dummy chip with a CPW trace (FIG. 18A), a test board with an alignment structure at the center and a CPW trace on the right (FIG. 18B), a three-dimensional stitch-chip assembled on the test vehicle (FIG. 18C), and the test vehicle being wire bonded (FIG. 18D).

FIG. 19A is a graph characterizing profilometer measurements of a stitch-chip assembly according to some embodiments.

FIG. 19B is an X-ray image of the assembly of FIG. 19A.

FIG. 20A is a top down view of an assembled three-dimensional stitch-chip on a test vehicle for RF measurements according to some embodiments.

FIG. 20B is a VNA measurement set up according to some embodiments.

FIGS. 20C-20F are graphs of RF measurement results according to some embodiments.

### DETAILED DESCRIPTION OF EMBODIMENTS

The present invention now will be described more fully with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the scope of the invention to those skilled in the art. Like reference numerals refer to like elements throughout.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer, or section. Thus, a first element, component, region, layer, or section discussed below could be termed a second element, component, region, layer or section without departing from the teachings of the present invention.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprising”, “including”, “having” and variants thereof, when used in this specification, specify the presence of stated features, steps, operations, elements, and/or components, but do not preclude the presence or addition of one or more other features, steps, operations, elements, components, and/or groups thereof. In contrast, the term “consisting of” when used in this specification, specifies the stated features, steps, operations, elements, and/or components, and precludes additional features, steps, operations, elements and/or components.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In some embodiments, a three-dimensional stitch-chip technology for chip-to-chip and chip-to-package interconnections are provided across varying transition lengths and heights. In particular, through via chiplets are incorporated into a three-dimensional stich-chip architecture for vertical signal transitions, which accommodates vertical step height without the need for die-embedding cavities and enabling face-up mounting with minimal detuning. Three-dimensional stitch-chips according to some embodiments may achieve high electrical performance with simplified assembly. In some embodiments, three-dimensional stitch-chips as described herein may be suitable for radio frequency (RF) applications. In addition, the three-dimensional stitch-chip may have a direct die-to-package contact that may enhance thermal dissipation without necessitating or relying on solder bumps, which may improve efficient thermal management when compared to traditional flip-chip configurations. In some embodiments, three-dimensional stitch-chips may be used in a single-chip configuration; however, complex multichip modules may also be used due to a modular design and flexible pitch adaptation.

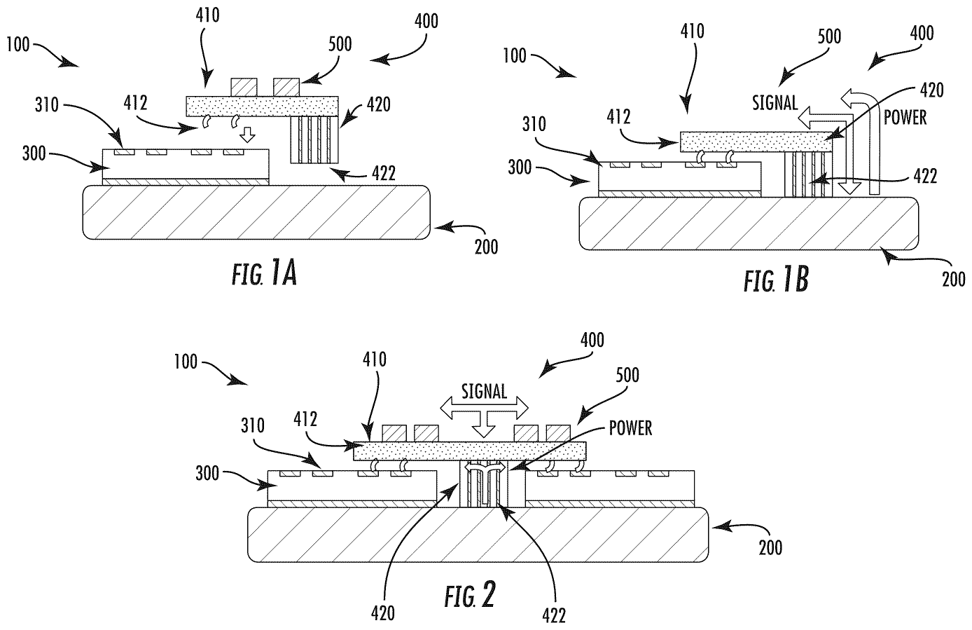

As illustrated in FIGS. 1A-1B, a semiconductor device 100 includes a substrate 200 and an integrated circuit chiplet 300 is on the substrate 100. A three-dimensional stitch-chip 400 is configured to electrically connect the substrate 200 to the integrated circuit chiplet 300. The three-dimensional chiplet 400 may include a bridging chiplet 410 that is configured to electrically connect to the integrated circuit chiplet 300, and a through via chiplet 420 that is configured to provide a vertical signal transmission path to the bridging chiplet 410. The through via chiplet 420 may include connections 422 that electrically connect to the substrate 200.

The integrated circuit chiplet 300 may include contacts 310 on a top surface thereof, and the bridging chiplet 410 may include corresponding contacts 412 to connect to the contacts 310 of the integrated circuit chiplet 300. As illustrated in FIG. 1B, power and/or signals to or from the substrate 200 may be conveyed through the electrical connection of the three-dimensional stitch-chip 400. Although the bridging chiplet 410 in FIGS. 1A-1B extends to one side of the through via chiplet 420 to form an “L” shape and connect to one integrated circuit chiplet 300, other configurations may be used.

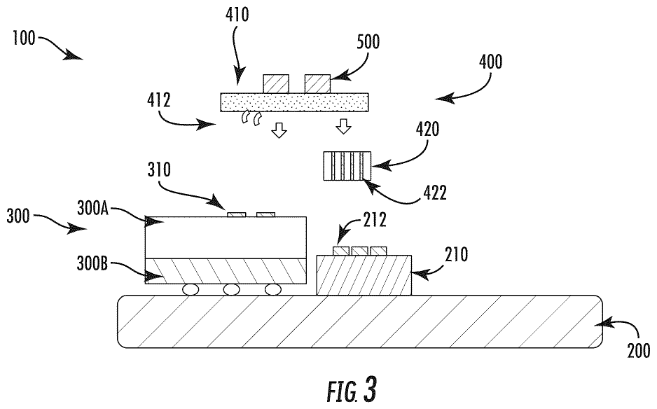

As shown in FIG. 2, the three-dimensional stitch-chip 400 may connect to more than one integrated circuit chiplet 300. The bridging chiplet 410 of the three-dimensional stitch-chip 400 of FIG. 2 extends in a “T” shape on both sides of the through via chiplet 420 to connect to two integrated circuit chiplets 300. In this configuration, the electrical connect from the substrate 200 to and from the integrated circuit chiplets 300 may provide a signal or power connection.

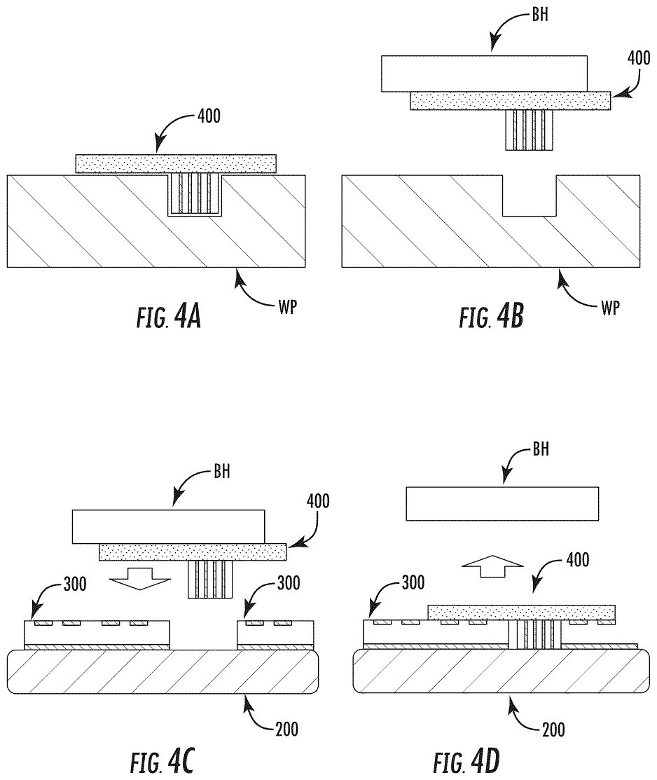

The substrate 200 may be any suitable substrate such as a wafer formed of materials such as silicon, gallium arsenide, silicon carbide, indium phosphide, sapphire and the like. In some embodiments, the substrate 200 comprises a printed wiring board (PWB), a package substrate, an interposer, a heat spreader. In some embodiments, one or more electrical components may be between the three-dimensional stitch-chip 400 and the substrate 200. For example, as illustrated in FIG. 3, a semiconductor die 210 including connections 212 is electrically connected to the substrate 200 and is configured to electrically connect to the through via chiplet 420 of the three-dimensional stitch-chip 400. The bridging chiplet 410 is configured to connect to the integrated circuit chiplet 300. Although the electrical component is illustrated in FIG. 3 as a semiconductor die 210, any suitable electrical component may be used. In some embodiments, the semiconductor die 210 may be replaced with a through via chiplet, i.e., so that a plurality of through via chiplets 420 may be stacked as part of the three-dimensional stitch-chip 400.

As further shown in FIG. 3, the integrated circuit chiplet 300 may include more than one chiplet such as two dies 300A, 300B such that the three dimensional chiplet 400 is configured to connect to electrical components of various heights. Electrical connections between components of the device 100 may be provided by solder bumps or compressible micro-interconnects (CMIs), including the connections 412 and 422.

The bridging chiplet 410 may be a component that connects a structure to a different transmission line and acts as a bridge to transfer signals between different components. The bridging chiplet may be configured to reduce signal reflection and loss over a frequency range while maintaining signal integrity. An example of a bridging chiplet 410 is a transitioning coplanar waveguide.

The through via chiplet is a vertical electrical connection that typically passes through a die or wafer, such as a silicon die, such as a through-silicon via (TSV). Accordingly, the through via chiplet may provide a vertical connection which allows chiplets to be stacked on each other or to allow a connection through a common interposer. Through via chiplets may permit vertical connections that are typically shorter than traditional wire bonds, reduce signal transmission distance. The through via chiplet may be a high-resistivity silicon chiplet that is formed of silicon material with a low concentration of dopants resulting in high electrical resistance or glass.

The decoupling capacitor(s) 500 may be capacitors used to suppress voltage fluctuations or noise on power supply lines, thereby reducing or minimizing the impact on the operation of sensitive components. Voltage ripples may be reduced, and voltage drops may be reduced or minimized during transient events to provide a stable and clean power supply to other components. In the case of high-frequency monolithic microwave integrated circuit (MMIC) amplifiers with broadband gain, protection from RF noise on the supply lines may be used. Supply noise can mix with RF signals, impacting signal-to-noise ratios and potentially causing spurious output. A decoupling (bypass) capacitor may provide an efficient path to the ground for RF energy on the supply line before it enters a gain stage.

Decoupling capacitors may be made of ceramic (including MLCC), electrolytic, and tantalum materials. Decoupling capacitors may be CMOS process compatible: Silicon/GaAs/GaN with multi-layer routing.

For the 3D-stitch-chip applications according to some embodiments, ceramic capacitors, CMOS-compatible capacitors, and some novel single-layer capacitors may be used as a decoupling capacitor 500. In some embodiments, the capacitor is mounted/fabricated above or embedded inside the bridging chiplet 410. In some embodiments, electrical components of the three-dimensional stitch-chip 400, including the decoupling capacitor 500, can be placed relatively close to die pads (I/Os) such that less loss and parasitic effects may be introduced, and the functions (filtering, coupling, gain, etc.) can be well maintained.

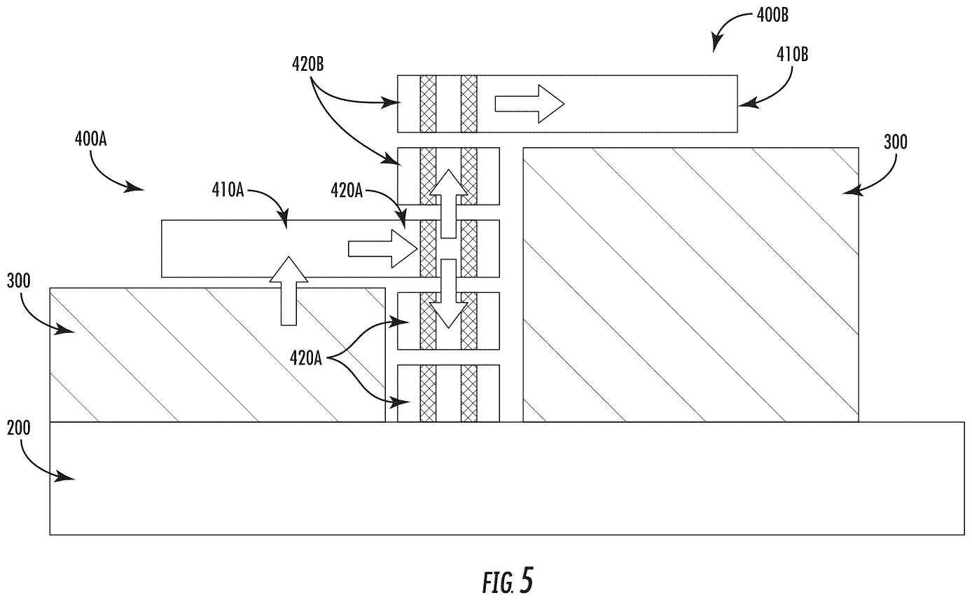

In some embodiments, a three-dimensional stitch-chip 400 may be positioned on a semiconductor device as illustrated in FIGS. 4A-4D. As illustrated in FIG. 4A, one or more three-dimensional stitch-chips 400 may be provided on a waffle pack WP, such as a silicon or glass waffle pack. In some embodiments, an array of three-dimensional stitch-chips 400 may be provided on the waffle pack WP. As illustrated in FIG. 4B, the three-dimensional stitch-chip 400 may be removed from the waffle pack WP, for example, by a bonder head BH or other die bonder that may be used to pick up the three-dimensional stitch-chip 400 and mount them to a semiconductor device as shown in FIGS. 4C-4D. In some embodiments, the placement of the three-dimensional stitch-chip 400 by the bonder head BH may be automated.

The three-dimensional stitch-chips according to some embodiments may include various configurations of bridging chiplets and through via chiplets and may be configured to connect one or more integrated circuit chiplets on a substrate. In addition, an additional through via chiplet may be incorporated into or be coplanar with the bridging chiplet. Moreover, the substrate may be a semiconductor package substrate and/or may include additional integrated circuit chips.

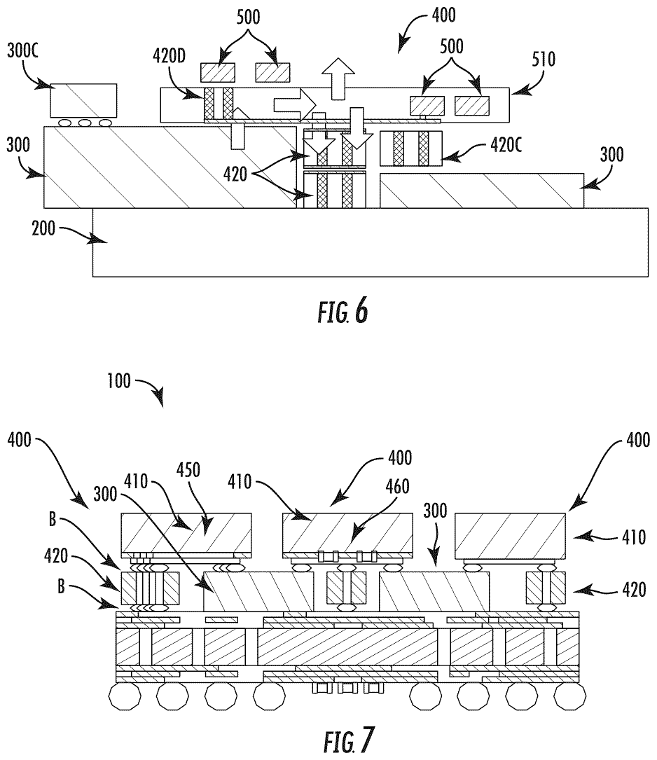

For example, as shown in FIG. 5, two integrated circuit chiplets 300 of different heights are on a substrate 200. A first three-dimensional stitch-chip 400A includes three through via chiplets 420A and a bridging chiplet 410A that connects to the substrate 200 and one of the integrated circuit chiplets 300. A second three-dimensional stitch-chip 400B includes a bridging chiplet 410B and two through via chiplets 420B. The topmost through via chiplet 420A of the three-dimensional stitch-chip 400A is in or embedded in the bridging chiplet 410A and is electrically connected to the substrate 200 through the lower two through via chiplets 420 and to additional through via chiplets 420B of a second three-dimensional stitch-chip 400B.

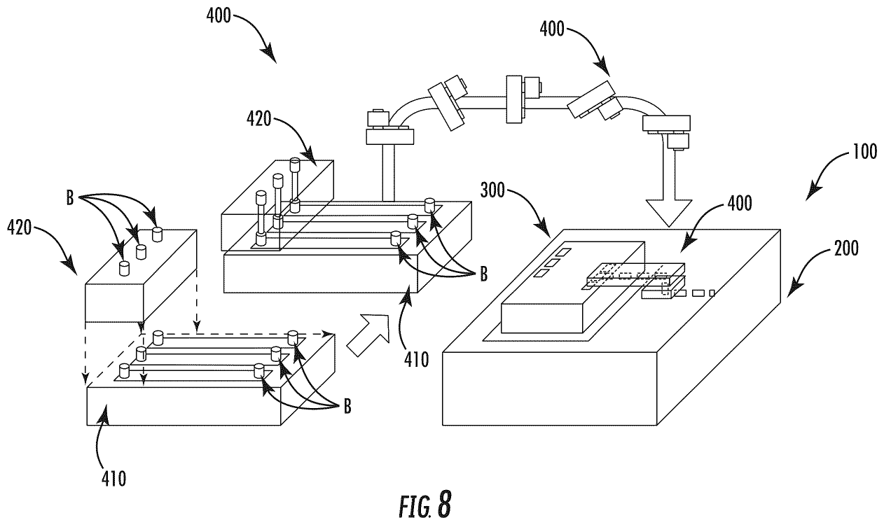

As illustrated in FIG. 6, two integrated circuit chiplets 300 of different heights are on a substrate and connected by a three-dimensional chiplet 400. An additional integrated circuit chiplet 300C may be electrically connected to one of the integrated circuit chiplets 300 by solder bumps. As illustrated in FIG. 6, the three-dimensional stitch-chip 400 includes a bridging chiplet 410 that extends in two directions to form a T-shaped three-dimensional stitch-chip 400 with stacked through via chiplets 420. An additional through via chiplet 420C is provided one the shorter or rightmost integrated circuit chiplet 300 to connect to the bridging chiplet 310, and a through via chiplet 420D may also be embedded in the bridging chiplet 410. Decoupling capacitors 500 may be positioned on the bridging chiplet 410 or may be embedded in the bridging chiplet 410. In this configuration, the three-dimensional chiplet 400 may be used to connect to integrated circuit chiplets 300 of different heights.

Nonlimiting examples according to some embodiments will now be described.

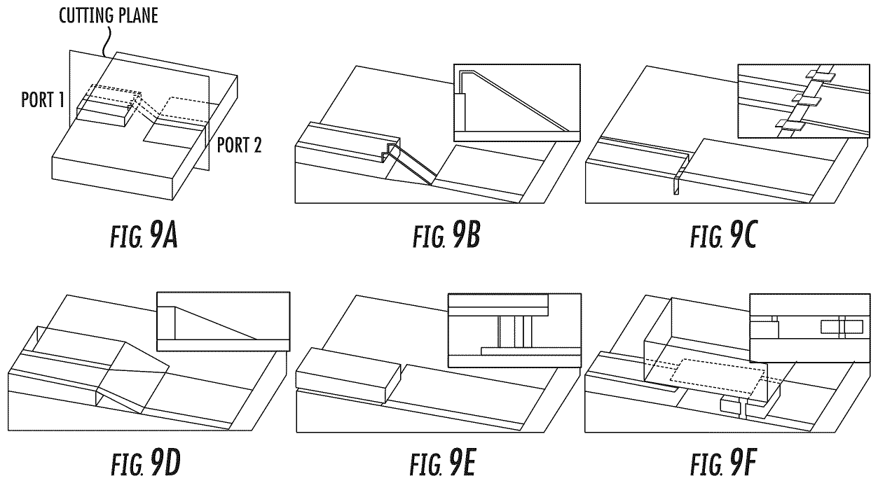

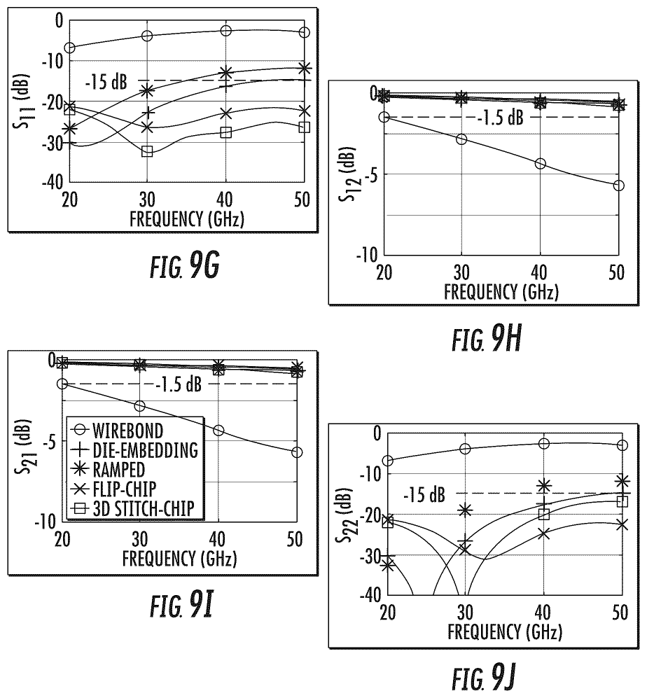

Because the three-dimensional stitch-chip is a combination of lateral and vertical signal paths, the constituent components have been simulated and optimized as a whole. As shown in FIGS. 7 and 8, bumps B were used at the interface between the bridging chiplet 410 (referred to in this example as a stitch-chip) and the through via chiplet 420 (referred to in this example as a TSV chiplet), as well as at the interfaces between the three-dimensional stitch-chip and the test vehicle. Accordingly, the signal chain in the three-dimensional stitch-chip starts with the bump on the chip-side of the test vehicle, stitch-chip, bump, TSV block, and ends with the bump to the board-side of the substrate. In this work, gold stud bumps were used on the stitch-chip and electroplated copper caps were formed on the TSV chiplet. The three-dimensional stitch-chip was designed for the Ka-band, whose frequency band ranges 26-40 GHz. Accordingly, full-field electrical simulation from 20 to 50 GHz was performed using Ansys HFSS. The silicon TSV chiplet and the fused-silica stitch-chip were first individually simulated and optimized, then brought together in subsequent simulations to optimize the whole signal chain.

Although some embodiments are referred to herein with respect to RF/mm-wave signals, it should be understood that the invention is not limited thereto. Embodiments according to the present invention may be used for both digital signals and RF/mm-wave signals.

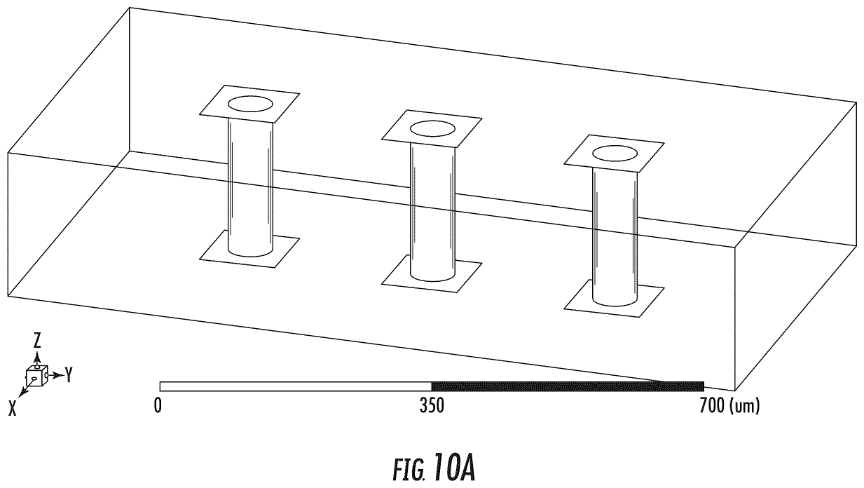

Various interconnect types, namely wire-bond, die-embedding, ramped interconnect, flip-chip, and three-dimensional stitch-chip, were simulated and compared against each other as illustrated in FIGS. 9A-9J. In FIG. 9A, port 1 is the chip side and port 2 is the board side, with the cutting plane used to clip the simulation models. FIGS. 9B-9E illustrate wire-bonding connections (FIG. 9B), die embedding connections (FIG. 9C), a ramped interconnect (FIG. 9D), and flip-chip bonding (FIG. 9E). FIG. 9F illustrates a three-dimensional stitch-chip according to embodiments of the current invention. The various test scenarios involved multiple realistic configurations of a 1×1×0.2 mm silicon chip on a 2.5×4×0.5 mm FR4 board. The models, depicted in FIGS. 9A-9F, were terminated at the chip for port 1 and at the package for port 2, with a 2.5 mm lateral separation between the two ports. The boards, which are 4 mm wide, are shown cut in half in the figures to provide a cross-sectional view. The electrical simulation results of the various interconnects shown in FIGS. 9G-J revealed that the wire-bond displays high insertion loss and suboptimal return loss, due to its highly inductive parasitic behavior. The ramped interconnect did not meet the 15 dB return loss target, but adjustments to ramp material and trace design may improve results, aided by the flexibility of additive manufacturing. The three other interconnection methods met the specifications in the frequency range of interest, with small differences in the frequency and intensity of resonance peaks.

Specifics of the simulation model are now described. FIG. 9B shows wire-bonds with the loop height and loop length parameters set to 100 and 550 μm, respectively. 25 μm (approximately 1 mil) thick gold wire was used in the model. All traces in this model were 5 μm thick copper. In the die-embedding case, as depicted in FIG. 9C, the chip was embedded in a cavity, employing a coplanar topology. The 50 μm wide cavity along the four sides of the chip was assumed to be filled with polyimide and leveled. A 50 μm wide and 100 μm long trace was placed at the chip-board interface to provide connectivity. An additively manufactured ramped interconnect is shown in FIG. 9D, with a polyimide ramp that guides the board trace up to the die trace. FIG. 9E reveals the flip-chip implementation, where copper bumps with 25 μm diameter and 25 μm height were placed at the interface. Finally, the three-dimensional stitch-chip was used to interconnect the chip and the board in FIG. 9F. To create a fair comparison across the four interconnection types, the via pitch of the ground-signal-ground (GSG) TSV was varied, and the best performing pitch was selected. The optimized pitch values were 180 μm for the wire-bond and the die-embedding cases, 250 μm for the three-dimensional stitch-chip, and 300 μm for the flip-chip case. In the ramped interconnect, the interconnect traces tapered linearly. The interconnection region of each model is highlighted in a zoomed-in inset. 50 Q CPW traces were placed on both the chip and the board. The chip CPW W, S, and L parameters were 100, 55, and 1000 μm, respectively, and the board CPW W and S parameters were 240 and 30 μm, respectively. The board CPW trace length varied with a maximum length of 1.5 mm because the different interconnection methods changed the level of chip-board trace separation. In the wire-bonding case, the board trace had a 500 μm lateral separation with the chip footprint. The results demonstrate that the three-dimensional stitch-chip achieves superior performance over traditional wire-bonding, meeting Ka-band frequency specifications with reduced insertion loss through the effective optimization of lateral and vertical signal paths.

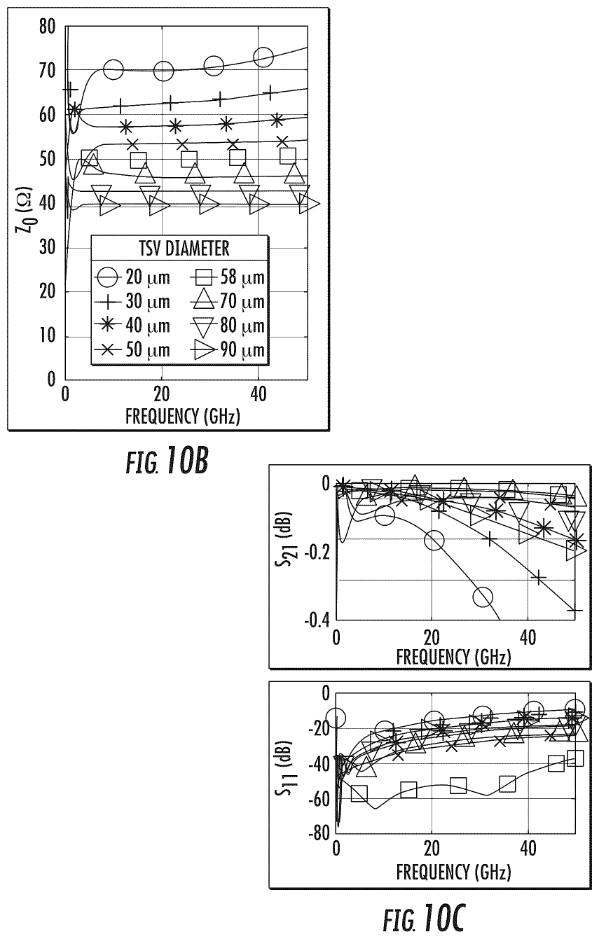

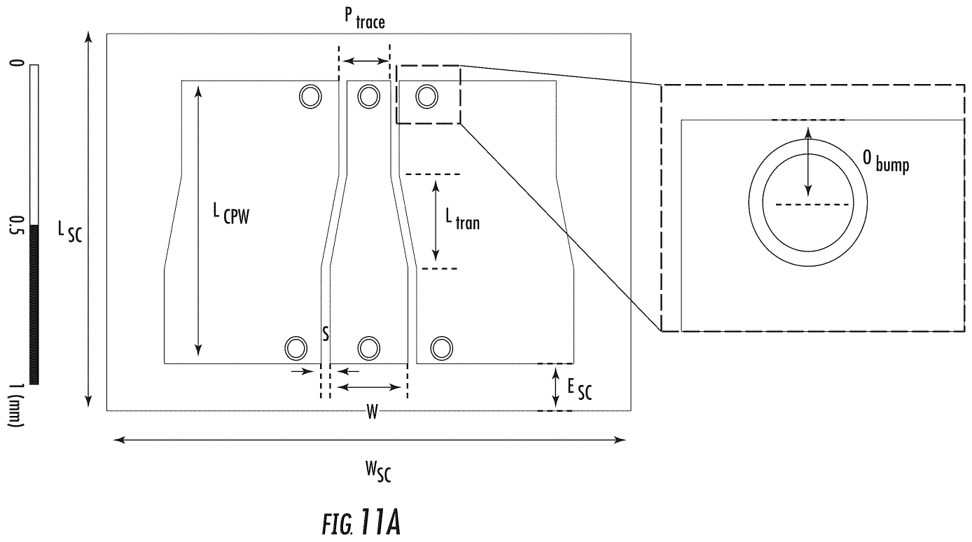

In designing the three-dimensional stitch-chip, various design parameters were analyzed and optimized to achieve acceptable electrical performance. Better than 15 dB return loss and better than 1.5 dB insertion loss were set as target values in the frequency band of interest.
1) TSV Chiplet: The TSV block transitions the signal vertically, catering to any height differences between the two connection points while the chiplet needs to maintain the 50 Q impedance. The characteristic impedance is essentially determined by the ratio between inductance and capacitance. This meant that the TSV diameter, pitch, as well as configuration of the return path vias all played a role in determining the characteristic impedance. Generally, thinner vias are more inductive, and vias closer together are more capacitive. Given the center-to-center TSV pitch of 250 μm, the TSV diameter parameter was parametrically analyzed. The silicon substrate width, length, and height were 500, 1000, and 300 μm, respectively. Landing pads were added to the top and bottom sides of the TSV in the simulation model, as shown in FIG. 10A These pads were given a width and length of 100 μm. The via diameter was parametrically analyzed to identify the diameter that yields 50Ω characteristic impedance. FIG. 10B reveals that the diameter of 58 μm yielded 50Ω impedance. The characteristic impedance is derived by

$${Z}_{0} = \sqrt{\frac{B}{C}}$$

where B and C are directly obtained from the ABCD matrix of the device under test (DUT) I. Ndip et al., “Analytical, numerical-, and measurement-based methods for extracting the electrical parameters of through silicon vias (TSVs)” IEEE Trans. Compon. Packag. Manuf. Technol., vol. 4, no. 3, pp. 504-515, March 2014. FIG. 10C plots the insertion loss and return loss, also revealing that the optimum design point is when D=58 μm.
2) Stitch-Chip: The stitch-chip serves as a critical component in the signal chain, bridging the differences in the bump pitch at the chip side and the board side. The design parameters of a pitch-transitioning CPW, shown in FIG. 11A, were optimized to minimize impedance discontinuities. In line with typical RFIC bare die pitch dimensions, 200 μm was set as the chip side bump pitch, which transitions into 250 μm pitch for connections to the TSV chiplet. The trace pitch P_{trace}, defined as the sum of the signal conductor width W and the slot width S, was constrained to the range between the bump diameter and the bump pitch. The initial trace pitch values were selected to be 200 and 250 μm at the chip side and the board side, respectively. The CPW dimensions at each end were then determined by R. N. Simons, Coplanar Waveguide with Finitewidth Ground planes, Hoboken NY, USA: Wiley, 2001, pp. 112-126 for target characteristic impedance Z₀=50Ω. The widths of the ground traces were designed to be at least twice the signal trace width W, ensuring they are wider than W+2×S to approximate infinitely large ground planes. G. E. Ponchak, E. M. Tenzeris, and L. P. Katehi, “Characterization of finite ground coplanare waveguide with narrow ground planes,” Int. J. Microcircuits Electron. Packag., vol. 20, no. 2, pp. 167-173, 1997. The two distinct 50 Q CPW traces on opposite ends of the stitch-chip required a smooth transition over some transition length Lₜᵣₐₙ, as displayed in FIG. 11A. The Sequential Mixed Integer Nonlinear Programming algorithm was used in Ansys HFSS to optimize the W, S, and transition length Lₜᵣₐₙ parameters. Considering the potential coupling between the fused silica stitch-chip and the silicon TSV block, the substrate extension parameter E_{sub} and bump offset parameter O_{bump} were also explored in the optimization process. The substrate extension refers to the additional length of substrate material that extends beyond a metal trace and contributes to the overall substrate length

$${L}_{SC} = 2 \times {E}_{sub} + {L}_{CPW} .$$

The optimized design was compared against the initial design in FIG. 11B, demonstrating considerable improvements in both insertion loss and return loss. It was noted in the optimization process that little correlation was found between the transition length Lₜᵣₐₙ and loss parameters. The total trace lengths were kept same across these variations. In the optimized design, the signal width W of the stitch-chip was 172 and 227 μm on each side, while the transition length Lₜᵣₐₙ was 500 μm. The entire stitch-chip substrate measured 1.8×1.4×0.5 mm (W_{SC}×L_{SC}×H_{SC}).

A time-domain reflectometry (TDR) analysis was conducted using the simulated S-parameters in Keysight ADS to evaluate the time-domain response and identify any impedance discontinuities, indicated by inductive spikes or capacitive dips in the TDR waveform. TDR response at the chip side is shown in FIG. 11C, using Tᵣ of 5 ps, which provided enough spatial resolution to identify two separate impedance discontinuities at the bumps. A 20 ps delay was introduced to better identify the peaks, and a Hamming window function was used. 56Ω and 58Ω spikes were observed. The latter peak is larger because of the greater bump pitch at the board side. The slight inductive peak may be advantageous in countering the capacitive effect in the trace overlap when flip-chip bonded. Overall, the TDR results indicate that the optimization process results in a smooth pitch transition, thereby reducing both insertion and return losses.

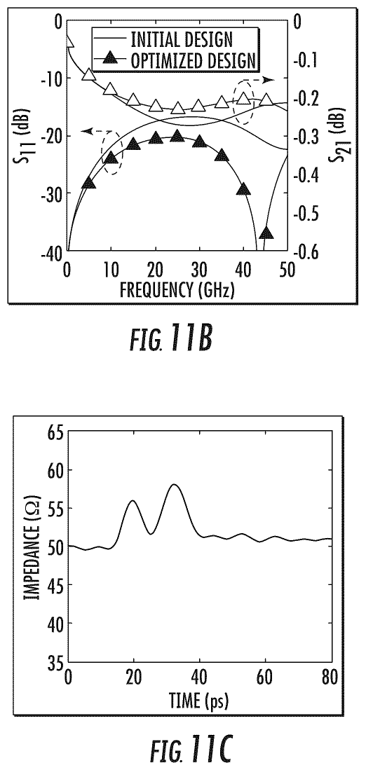

The high-frequency behavior of the assembled three-dimensional stitch-chip was studied and summarized below. The three-dimensional stitch-chip model was assembled atop a test vehicle, which resembles the configuration shown in FIGS. 3A and 3D, with additional updates to the model. The three-dimensional stitch-chip was then built on top of the test vehicle, as shown in FIG. 12A. At certain points along the trace, the designed CPW may drift out of tune due to the proximity of certain dielectric materials. This meant that the electrical simulations were critical in identifying such issues and establishing key parameters that had a large impact on the overall performance. Among many parameters that were simulated, TSV chiplet size and bump dimensions are examined to help understand the design optimization process.

The first of the two parameters is the TSV chiplet dimensions, namely its width and length, as seen in FIG. 12A. With the chiplet length fixed at 500 μm, the chiplet width was varied from 1 to 2 mm. Similarly, the chiplet width was fixed at 1 mm and the chiplet length was varied from 200 to 800 μm. As evidenced by FIG. 12B, the impact of the chiplet width was minimal. This was as expected, as most of the field would be contained in the vicinity of the slot between the board CPW signal and ground. FIG. 12C shows that the chiplet length has a profound impact on the return loss behavior, with a design optimum at L=500. In general, a smaller chiplet footprint near the transition was desired, but very small lengths tuned the TSV impedance out of design. The conclusion from this parametric analysis was that two design changes could be made. The first design recommendation resulting from this study was to reduce the TSV chiplet size as permitted by the fabrication process. The second option was to create compensation structures on the board trace itself. The former approach was chosen, in the opinion that the three-dimensional stitch-chip design must be as flexible and substrate-agnostic as possible. The smaller TSV chiplet footprint was expected to reduce the dielectric loading effect yet it remains large enough to contain most of the fields between the TSVs. Smaller TSV blocks with the diameter tuned to 50Ω may reduce the loading effect even further, but it might become difficult to handle during microfabrication and assembly. The target design parameter was set at W=1000, L=500 μm, finding a balance between manufacturing feasibility and electrical performance.

The second of the two parameters is the bump dimensions, also highlighted in FIG. 12A. The main role of the bump was to provide electrical and mechanical connectivity, while also separating the three-dimensional stitch-chip from the chip and the TSV chiplet from the stitch-chip. In addition, the diameter of the bump must remain small enough that the bump capacitance will not negatively affect high-frequency performance. The gold stud bumps on the stitch-chip were analyzed. First, the bump height was set at 50 μm, and its diameter was varied; the simulation results are displayed in FIG. 12D. There is a trade-off in the return loss behavior, where larger bumps enhance performance at higher frequencies but they degrade performance at lower frequencies. The crossover happens at the valley of the resonance. In order to find a balance in the entire Ka-band, 60-80 μm was chosen as an acceptable value for the bump diameter parameter. The bump height was also explored and plotted in FIG. 12E. A similar trade-off can be observed; decreasing the bump height improved lower frequency return loss but it worsened higher frequency characteristics. Bump height of 50 μm displayed the best compromise across the design bandwidth of 26-40 GHz. Local compensation structures such as high-impedance or ground retreat introduced in CL Wang and RB Wu, “Modeling and design for electrical performance of wideband flip-chip transition,” IEEE Trans. Adv. Packg., vol. 26, no. 4, pp. 385-391, November 2003, were tested in the simulations. However, neither method was appropriate. The inductive compensation structure introduced excessive reflection, and ground retreat could not be physically implemented due to pitch constraints.

A test vehicle was designed to mimic a configuration where an RF die is packaged onto a package or substrate. In the test vehicle, a 1.8×1.4×0.3 mm (L×W×H) dummy silicon chip was mounted at the center of an 8×8×0.5 mm (L×W×H) dummy fused-silica board. CPW traces were created on both the dummy chip and the glass board so that a chip-interconnect-board signal chain could be simulated, assembled, and measured.

In order to better capture the differences between various interconnection methods, high resistivity silicon (HR-Si) was used as the substrate material for the dummy chip. A 2 μm-thick silicon dioxide (SiO₂) layer was added on the top and bottom sides for passivation. The CPW started at the centerline along the length of the dummy chip and ended at the edge of the dummy chip. The backside of the chip was fully metallized, effectively creating a CPW with a floating metal at the bottom. The test chip backside was metallized to better mimic MMICs, which often have a solid ground plane on the backside of the chip. This also ensured that any inconsistency in the die-attach interface would not lead to variation in the CPW behavior, as the field would be maintained within and above the chip. The chip GSG pads were designed with 200 μm pitch, and the glass traces were designed with 300 μm pitch. Lumped ports with the aforementioned pitch values were created and placed at each end of the test vehicle.

The fused-silica material was selected as the package material in accordance with the increasing interest in glass packaging. A 1-mm long CPW trace was created, beginning after a horizontal separation of 700 μm from the dummy chip to provide space for the three-dimensional stitch-chip or wire-bond interconnection. A rectangular metal patch of the exact dimensions of the dummy chip was added to the center of the board, facilitating alignment in the bonding process. The final target design parameters are summarized in Table I.

TABLE I
TARGET VALUES FOR THE DESIGN PARAMETERS

| Parameter | Value | |
|---|---|---|
| Dummy chip w, l, h | 1.4, 1.8, 0.3 | mm |
| CPW l | 900 | μm |
| CPW w_{sig}, s, w_{gnd} | 100, 50, 300 | μm |
| Oxide liner t | 2 | μm |
| Stitch-chip w, l, h | 1.8, 1.4, 0.5 | mm |
| CPW l, lₜᵣₐₙ | 900, 500 | μm |
| Chip-side bump pitch p | 200 | μm |
| Chip-side CPW w_{sig}, s, w_{gnd} | 172, 28, 450 | μm |
| Broad-side bump pitch p | 250 | μm |
| Broad-side CPW w_{sig}, s, w_{gnd} | 227,23, 480 | μm |
| Gold bump d, h | 80, 50 | μm |
| Bump offset O_{bump} | 50 | μm |
| Edge extension factor E_{SC} | 250 | μm |
| TSV chiplet w, l, h | 0.5, 1, 0.3 | mm |
| TSV p, h, d | 250, 300, 58 | μm |
| TSV cap d, h | 80, 30 | μm |
| Oxide, nitride liner t | 500, 300 | nm |
| Package w, l, h | 8, 8, 0.5 | mm |
| Package CPW l | 1000 | μm |
| Package CPW w_{sig}, s, w_{gnd} | 240, 30, 800 | μm |

The fabrication process of the three-dimensional stitch-chip and test components is described in this section. In the first part, the fabrication of the three-dimensional stitch-chip is detailed. In the second part, the test vehicle fabrication process is outlined. In the last part, the assembly process is illustrated.

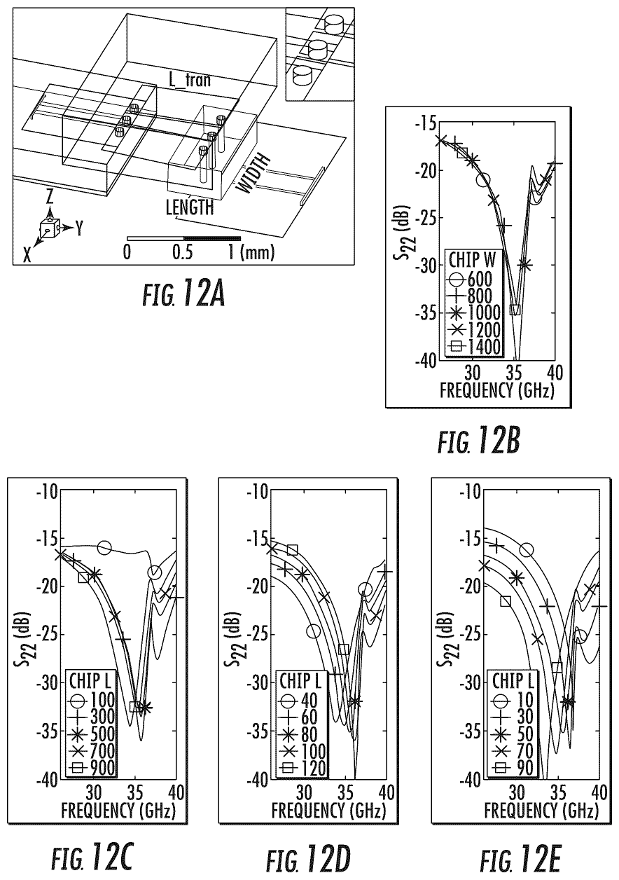

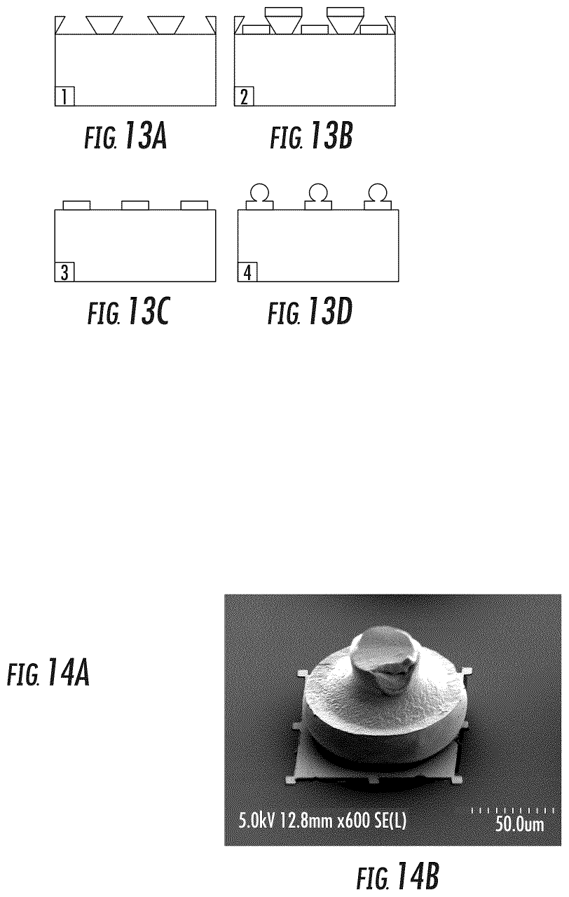

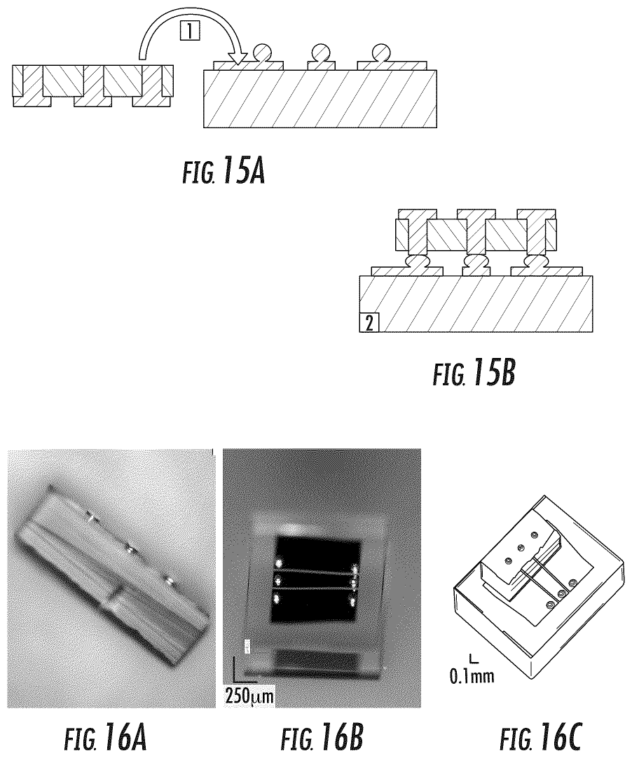

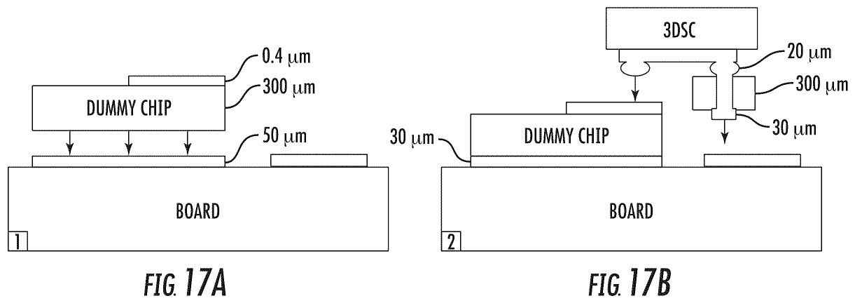

The fabrication steps used to manufacture the three-dimensional stitch-chip will be described. FIGS. 12A-13D illustrate the stitch-chip process flow, and FIGS. 14A-14B presents the corresponding process images. FIGS. 15A-15B highlights the three-dimensional stitch-chip assembly process flow, while the fabricated components are depicted in FIGS. 16A-16C.

The fabrication of the stitch-chip with a compressible microinterconnect (CMI) interface is described in T. Zheng and MS Bakir, “Fused-silica stitch-chips with compressible microinterconnects for embedded RF/mm-wave chiplets,” IEEE MTT-S Int. Microw. Symp. Dig. Denver, CO USA, June 2022, pp. 583-586. In this work, gold stud bumps were used in place of the CMIs because of ease of fabrication and assembly. The process flow is outlined in FIGS. 13A-13D. To fabricate the CPW traces, a stack of metals (titanium, copper, and gold) was evaporated onto patterned openings on the spin-coated photoresist (Futurrex Negative Resist NR9-1500PY). The metal deposited onto the photoresist was lifted off in an acetone bath. The wafer was diced into smaller chips for easier handling during stud bump formation. Temporary alignment markers were photo-defined for accurate placement of the stud bumps [FIG. 14A]. Both positive and negative tone photoresist processes were explored, but it was found that alignment markers formed with negative photoresist were difficult to remove due to thermal cross-link induced during wire-bonding on a heated bonding stage.

To facilitate electrical and mechanical bonding between different components, gold stud bumps were fabricated onto the stitch-chip [FIG. 14B]. TPT HB16 semi-automatic wire bonder fit with a ball bond tip was used to form the gold bumps. The formed gold bumps had an approximate diameter of 90 μm. After stud bump formation, the sample was singulated [FIG. 16B].

TSV chiplets were created by first fabricating the TSVs to the specified size and pitch followed by dicing the wafer to yield standalone chiplets. The silicon was etched with deep reactive ion etching (DRIE) and a 500-nm thick SiO₂ was grown to serve as the liner layer. Silicon nitride (Si₃N₄) was also deposited to act as an etch stop layer during the polishing step.

The via was filled with copper in a two-step process: backside pinch-off plating and bottom-up plating. To localize copper growth on the backside of the wafer in the pinch-off plating process, RY5125 dry-film photoresist was vacuum-laminated, and circular openings were patterned onto the film, creating an 80 μm diameter and 30 μm tall copper cap. This cap only exists on one side of the TSV chiplet, enabling bonding to the board traces. A two-step chemical mechanical polishing (CMP) process was performed, where the copper caps were first mechanically polished to reduce the global thickness variation, and then finely polished to reduce local roughness. FIG. 16A shows the side view of the fabricated TSV chiplet with the copper caps on the surface.

The final step of three-dimensional stitch-chip fabrication is to bond the TSV chiplet to the stitch-chip, as depicted in FIGS. 15A=15B. The two components were bonded at 290° C. using a flip-chip bonder. Prior to bonding, the bonding pads, which use copper for the TSV chiplet and gold for the stitch-chip, were treated with Ar plasma at 150 W for 30 s. The fabricated three-dimensional stitch-chip sample is shown in FIG. 16C.

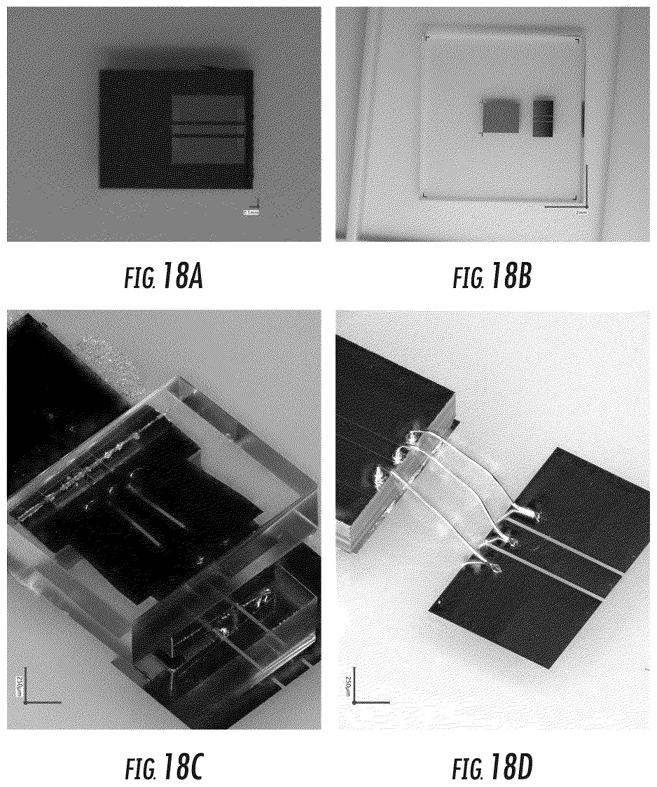

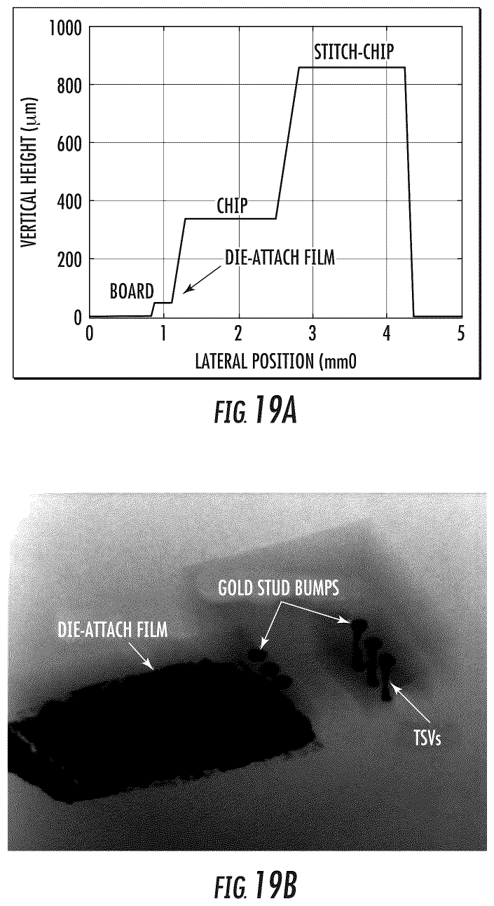

To provide an interconnection scenario, two distinct dice were fabricated: (a) the dummy chip with a CPW trace, and (b) a test board with alignment structures and CPW traces. The dummy chip has CPW trace on the top and a metal plane at the bottom for shielding [FIG. 18A]. To fabricate the dummy chip, a silicon wafer is first insulated with 2 μm thick thermally grown SiO₂. Metal traces consisting of titanium, copper, and gold films were created using a lift-off process. The wafer backside was then metallized with titanium and gold layers, creating a blanket metal layer that acts as a floating ground. The test board emulating a package substrate was fabricated using a 500-μm thick fused silica wafer [FIG. 18B]. Fiducials, die paddle for die-attach, and CPW trace were all fabricated by one lift-off step. The wafer was then diced into 8 mm 8 mm chips. The dummy chip was attached to the die paddle on the test board (i.e., glass package) using a 2 mil thick conductive epoxy film as described in FIG. 17A-17B.

The three-dimensional stitch-chip was flip-chip bonded onto the test vehicle using the Finetech FINEPLACER lambda bonder. The assembly process is illustrated in FIG. 17A-17B, and the assembly result is pictured in FIG. 18C. A thermo-compression bonding process with 290° C. on the chip side and 260° C. on the substrate side was used.

To ensure alignment across the height difference between the three-dimensional stitch-chip and the dummy chip, a small silicon support piece was used to position the three-dimensional stitch-chip upright. This setup allowed the bonder to securely pick up the three-dimensional stitch-chip by the glass portion and align it accurately to the dummy chip at the required height. This technique accommodated the nonplanarity of the three-dimensional stitch-chip during bonding, achieving a stable attachment across varying heights. To characterize the bond strength, destructive die shear testing was performed on the bonded assembly using XYZTec CONDOR bonding tester. The three-dimensional stitch-chip sustained 440 gf before it was sheared off from the test vehicle. Various shear force values have been reported for gold stud bump connections, with one study reporting a range of 15-100 gf per bump depending on bonding conditions and thermal aging, F. Li, “Flip chip bonding for sic integrated circuits with gold stud bumps for high temperature up to 6000 applications,” IEEE Trans. Compon., Packag., Manuf Technol., vol. 14, no. 4, pp. 551, 559, April 2024. One potential issue introduced by the high bonding temperature was the reflowing of conductive epoxy film used to attach the dummy chip, which negatively affected the planarity of the chip. One promising alternative is to utilize low-temperature thermosonic bonding.

To provide a baseline for comparison, one set of test vehicles was wire-bonded [FIG. 18D]. With a 1 mil gold wire, a double-reverse loop was formed from the dummy chip to the test board: the reverse loop improves loop stability by reducing the stress on the wire. Ball bonding was chosen due to fabrication readiness. The wire pitch was targeted at 200 μm on the chip side and 300 μm on the board side.

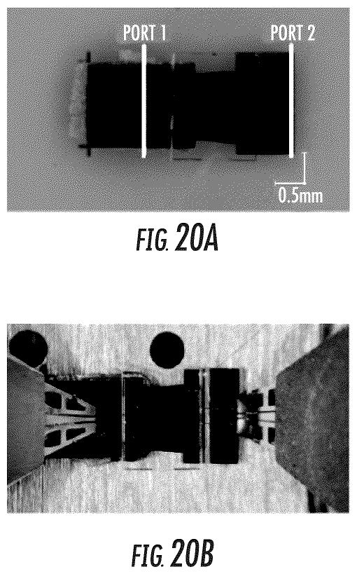

The cross-sectional profile of the assembled test vehicle was measured using a profilometer to assess the bump height and the flatness of the three-dimensional stitch-chip after the thermo-compression bonding. The measured profile is shown in FIG. 19A; it was evident that the flatness of the three-dimensional stitch-chip was maintained even after the assembly. Beginning from the left, the measurement started with a part of the 2 mil-thick epoxy film, followed by a 300 μm tall step that indicates the dummy silicon chip. Between the right edge of the chip and the top of the stitch-chip, a 522 μm tall step indicates that the gold bump, after compression, is approximately 20 μm tall. This indicates stronger compression than anticipated, further supporting the idea that the previously mentioned thermosonic bonding may offer benefits. On the far right, the profile drops to the board level.

An X-ray image was taken using an oblique angle in DAGE X-Ray XD7600NT and depicted in FIG. 19B. In the X-ray images, the darkness intensifies with both the material thickness and composition, with metals appearing significantly darker due to their higher density. The X-ray image shows that the fused-silica block sits atop the silicon TSV chiplet and dummy chip. The conductive epoxy film under the dummy chip is clearly visible. The TSVs and gold stud bumps can also be seen in this image. It is evident that the TSVs were not electroplated perfectly since the TSVs do not show a complete cylindrical shape in the image. Future work will focus on achieving more precise control over process parameters to ensure complete filling of the TSVs.

Using the same substrate material in the two components would be ideal for CTE matching. To improve CTE alignment, through-glass via (TGV) samples are also being explored for future designs.

In this section, the electrical characterization methods and results are presented. dc measurement, RF measurement, and the resulting data analysis are included. A dc resistance of 363.35 mΩ was measured across the signal net, spanning from the chip-side CPW to the board-side CPW, indicating that the gold bumps provided electrical connection as desired. The high-frequency performance was measured up to 50 GHz using Keysight N5245A PNA-X vector network analyzer (VNA) equipped with Cascade Microtech GSG |Z| probes. The reference plane was set to the probe tips using short-open-load-through (SOLT) calibration method. The chip and the board were measured using 200 and 300 μm pitch probes, respectively.

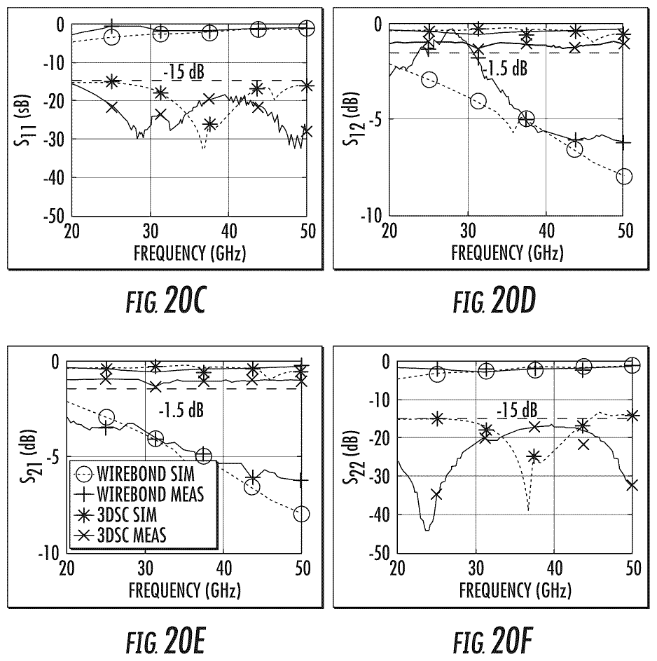

Based on visual inspection using an optical microscope, the actual gold stud bump dimensions were incorporated into the simulation model (to a diameter of 100 μm and a height of 20 μm). The imperfect TSV shape was not incorporated into the simulation model due to difficulties with precise visual inspection of the fabricated TSV geometry. The two ports were excited with lumped ports. Perfect electrical conductor (PEC) boundary condition was applied to the bottom side of the board. The RF chain begins with a 900 μm-long trace on the chip, 900 μm-long trace on the stitch-chip, 300 μm tall TSV, and then ends with a 1 mm-long trace on the package. There is a 100 μm overlap between each transition (i.e., between chip and stitch-chip, stitch-chip and TSV, and TSV and package). From the chip-side reference plane to the board-side reference plane, the lateral length is 2.5 mm and the vertical length is approximately 400 μm (combining three 30 μm tall bumps and 300 μm tall via), making the total signal length slightly shorter than 3 mm. FIG. 20A illustrates the position of each port (i.e., reference plane) and FIG. 20B pictures the measurement setup, where the chip-side port 1 is probed by the 200 μm pitch GSG probe and the board-side port 2 is probed by the 300 μm pitch GSG probe.

The simulation and measurement results are plotted in FIGS. 20C-20D. The wire-bonded and the three-dimensional stitch-chip results are plotted. The simulated data in dotted lines can be compared to the measured data in solid lines. Overall, the wire-bonded test vehicle showed good agreement between the simulation and measurement results in both reflection graphs. A small deviation in resonance peak location was observed in the three-dimensional stitch-chip, yet the magnitude of the resonance was maintained at −15 dB. This could be attributed to the process variations, such as conductor roughness or contact resistance.

The insertion loss S12 and S21 also presents noteworthy insights. The measured data of the wire-bonded test vehicle shows good agreement with the simulated data for the most part, except for a resonance peak at around 28 GHz in the S12 graph. The measured data with the three-dimensional stitch-chip showed an insertion loss approximately 0.63 dB greater than the simulated data in the Ka-band.

The three-dimensional stitch-chip can be improved in its performance, functionality, and manufacturability. First, a low-force bonding method can be utilized, such as thermosonic bonding, to reduce gold bump deformation. In addition, TGVs are emerging as a potential packaging solution across various industries. Glass-based interconnects benefit from superior electrical characteristics, holding promise for future development in this research as a replacement for the vertical signal transition.

In terms of functionality, design features, such as power delivery traces, embedded passives, and integrated passive devices (IPD), could be integrated into the three-dimensional stitch-chip. The high output power of certain RF devices, such as power amplifiers (PA), necessitates the analysis of current carrying capacity, potentially requiring thicker or wider traces. In the digital domain, multilayer signaling may allow high bandwidth signaling capabilities.

According to some embodiments, three-dimensional stitch-chips may be used as an advance packaging solution for the HI of RF chiplets. The three-dimensional stitch-chip m a y utilize the convenience of a wire-bonded package and improve signal integrity without the fabrication and circuit detuning challenges of die-embedding and flip-chip bonding methods. Detailed optimization processes were outlined for the constituent components and for the whole signal chain. The optimized three-dimensional stitch-chip design was fabricated and assembled onto the test vehicle for electrical and mechanical characterization, exhibiting better than 16.3 dB return loss and lower than 1.3 dB insertion loss in the Ka-band while maintaining strong bonds.

In the drawings and specification, there have been disclosed typical preferred embodiments of the invention and, although specific terms are employed, they are used in a generic and descriptive sense only and not for purposes of limitation, the scope of the invention being set forth in the following claims.

What is claimed is:

1. A semiconductor device comprising:
a substrate;
an integrated circuit chiplet on the substrate;
a three-dimensional stitch-chip configured to electrically connect the substrate to the integrated circuit chiplet, the stitch-chip comprising:
a bridging chiplet that is configured to electrically connect to the integrated circuit chiplet; and
a through via chiplet configured to electrically connect to the bridging chiplet configured to provide a vertical signal transmission path to the bridging chiplet.

2. The semiconductor device of claim 1, wherein the bridging chiplet comprises a pitch-transitioning coplanar waveguide.

3. The semiconductor device of claim 1, wherein the through via chiplet comprises a through-silicon via (TSV) chiplet.

4. The semiconductor device of claim 1, wherein the through via chiplet comprises a plurality of stacked through via chiplets.

5. The semiconductor device of claim 1, further comprising at least one decoupling capacitor electrically connected to the bridging chiplet.

6. The semiconductor device of claim 5, wherein the at least one decoupling capacitor is mounted on a top surface of the bridging chiplet.

7. The semiconductor device of claim 5, wherein the at least one decoupling capacitor is embedded in the bridging chiplet.

8. The semiconductor device of claim 1, wherein the three-dimensional stitch-chip is configured to reduce signal reflection and/or increase power transfer.

9. The semiconductor device of claim 1, further comprising compressible micro-interconnects on a bottom surface of the bridging chiplet electrically connecting the bridging chiplet to the integrated circuit chiplet.

10. The semiconductor device of claim 1, wherein the integrated circuit chiplet is a radio frequency integrated circuit.

11. The semiconductor device of claim 1, wherein the substrate is a printed wiring board (PWB), semiconductor package, an interposer, a chip, or a heat spreader.

12. The semiconductor device of claim 1, further comprising an electrical component between the three-dimensional stitch ship and the substrate.

13. The semiconductor device of claim 12, wherein the electrical component comprises a semiconductor die that is configured to connect to the through via chiplet of the three-dimensional stitch-chip.

14. A semiconductor device comprising:
a substrate;
a first integrated circuit chiplet on the substrate;
a second integrated circuit chiplet on the substrate;
a three-dimensional stitch-chip configured to electrically connect the substrate to the first integrated circuit chiplet and the second integrated circuit chiplet, the stitch-chip comprising:
a bridging chiplet that is configured to electrically connect to the first and the second integrated circuit chiplets; and
a through via chiplet configured to electrically connect to the bridging chiplet configured to provide a vertical signal transmission path to the bridging chiplet,
wherein the through via chiplet is between the first and second integrated circuit chiplets and the bridging chiplet extends away from the through via chiplet horizontally in opposing directions.

15. The semiconductor device of claim 14, wherein the first integrated circuit chiplet has a first height and the second integrated circuit has a second height that is greater than the first height.

16. The semiconductor device of claim 15, further comprising at least one additional through via chiplet configured to electrically connect the second integrated circuit to the bridging chiplet.

17. The semiconductor device of claim 14, further comprising at least one decoupling capacitor electrically connected to the bridging chiplet.

18. The semiconductor device of claim 14, wherein the bridging chiplet comprises a pitch-transitioning coplanar waveguide.

19. The semiconductor device of claim 14, wherein the through via chiplet comprises a through-silicon via (TSV) chiplet.

20. A three-dimensional stitch-chip configured to electrically connect a substrate to an integrated circuit chiplet, the stitch-chip comprising:
a bridging chiplet that is configured to electrically connect to the integrated circuit chiplet; and
a through via chiplet configured to electrically connect to the bridging chiplet configured to provide a vertical signal transmission path to the bridging chiplet.
